(19) United States
(12) Patent Application Publication
(10) Pub. No.: US 2023/0051023 A1
(43) Pub. Date: Feb. 16, 2023

(54) REFLECTIVE MASK BLANK, REFLECTIVE MASK, AND METHOD FOR MANUFACTURING SEMICONDUCTOR DEVICE

(71) Applicant: HOYA CORPORATION, Tokyo (JP)

(72) Inventor: Kazuhiro HAMAMOTO, Tokyo (JP)

(73) Assignee: HOYA CORPORATION, Tokyo (JP)

(21) Appl. No.: 17/794,202

(22) PCT Filed: Jan. 28, 2021
(86) PCT No.: PCT/JP2021/003001

§ 371 Date: Jul. 20, 2022

(30) Foreign Application Priority Data
Feb. 12, 2020 (JP) 2020-021112

(51) Int. Cl. G03F 1/24

(52) U.S. Cl. CPC G03F 1/24

(57) ABSTRACT

Provided is a reflective mask blank which includes an absorber film.

The reflective mask blank of the present invention is a reflective mask blank including a multilayer reflective film and a thin film for pattern formation in this order on a main surface of a substrate, in which the thin film contains tin, tantalum, niobium, and oxygen, and the oxygen deficiency rate of the thin film is 0.15 or more and 0.28 or less.

### CROSS-REFERENCE TO RELATED APPLICATIONS

This application is the National Stage of International Application No. PCT/JP2021/003001, filed Jan. 28, 2021, which claims priority to Japanese Patent Application No. 2020-021112, filed Feb. 12, 2020, and the contents of which is incorporated by reference.

### TECHNICAL FIELD

The present disclosure relates to a reflective mask blank which is an original form for manufacturing a transfer mask used for manufacturing a semiconductor device, etc., a reflective mask and a method of manufacturing the same, and a method of manufacturing a semiconductor device.

### BACKGROUND ART

A light source of an exposure apparatus in manufacture of semiconductor devices has evolved while gradually shortening the wavelength, and in order to realize finer pattern transfer, EUV lithography using extreme ultraviolet rays (EUV: Extreme Ultra Violet; extreme ultraviolet ray is hereinafter referred to as EUV light) having a wavelength around 13.5 nm is being developed. In EUV lithography, a reflective mask is used since there are not many materials that are transparent to EUV light.

Techniques related to a reflective mask for the EUV lithography and a mask blank for manufacturing the same are disclosed in Patent Documents 1 and 2.

### PRIOR ART PUBLICATIONS

### Patent Documents

[Patent Document 1]
Japanese Patent Application Publication 2004-039884
[Patent Document 2] International Publication WO 2019/009211

### SUMMARY OF THE DISCLOSURE

Problems to be Solved by the Disclosure

In EUV lithography, a projection optical system consisting of numerous reflecting mirrors is used. Then, EUV light is entered obliquely on a reflective mask so that the plurality of reflecting mirrors does not block the projection light (exposure light). An incident angle is currently generally 6° to a plane perpendicular to a substrate surface of a reflective mask. With the improvement of numerical aperture (NA) of a projection optical system, a study has been made to apply an angle of more oblique incidence of about 8°.

Since exposure light enters obliquely in EUV lithography, there is an inherent problem called shadowing effect. Shadowing effect is a phenomenon in which a shadow is formed when exposure light enters obliquely on an absorber pattern having a three-dimensional structure, causing changes in the size and/or position of the pattern to be transferred and formed. The three-dimensional structure of the absorber pattern acts as a wall so that a shadow is formed on the shade side, causing changes in the size and/or position of the pattern to be transferred and formed. For example, a difference occurs in the size and position of transfer patterns depending on whether the orientation of an absorber pattern to be arranged is parallel or vertical to the direction of the oblique incident light, causing reduction in transfer precision.

The finer the pattern and the higher the precision of the pattern size and/or the pattern position, the higher the electrical characteristics and performance of the semiconductor device, and the higher the integration degree and the smaller the chip size. In EUV lithography, fine size pattern transfer performance with higher precision than conventional cases is required. At present, formation of ultrafine and high-precision patterns corresponding to hp 16 nm (half pitch 16 nm) generation is required. In response to such a demand, further thinning of an absorber film is required in order to reduce the shadowing effect. In particular, in the case of EUV exposure, a film thickness of the absorber film is required to be 50 nm or less, preferably 40 nm or less.

On the other hand, a reflective mask is required to obtain a sufficiently high contrast between reflected light from an absorber pattern and reflected light from a multilayer reflective film when EUV light is irradiated. In order to satisfy this requirement, it is desirable that a reflectance of an absorber film with respect to EUV light is 1% or less.

As disclosed in Patent Document 1, a material containing tantalum as a main component (tantalum-based material) is conventionally applied to an absorber film of a reflective mask blank. However, an extinction coefficient k of a tantalum-based material to EUV light is not so high. Therefore, it is difficult to set a film thickness of an absorber film of a tantalum-based material to 50 nm or less while satisfying a reflectance required for an absorber film. On the other hand, a light absorbing layer (absorber film) formed of tin oxide (SnO) as disclosed in Patent Document 2 has a high extinction coefficient to EUV light and can have a film thickness of 50 nm or less while satisfying a reflectance required for an absorber film. However, an SnO absorber film has a problem of relatively low chemical resistance. In particular, resistance to SPM cleaning (cleaning with mixture liquid of sulfuric acid, hydrogen peroxide, and water) used in the process of manufacturing a reflective mask from a reflective mask blank is low, which has been a problem.

In view of the above, the aspect of the present disclosure is to provide a reflective mask blank for manufacturing a reflective mask where shadowing effect is further reduced, which also includes an absorber film with enhanced chemical resistance. The aspect of the present disclosure is to provide a reflective mask where shadowing effect is further reduced, which also includes an absorber pattern with enhanced chemical resistance. The aspect of the present disclosure is to provide a method of manufacturing a semiconductor device having a fine and highly precise transfer pattern by using the reflective mask described above.

### Means for Solving the Problem

To solve the above problems, the present disclosure includes the following configurations.

### (Configuration 1)

A reflective mask blank including a multilayer reflective film and a thin film for pattern formation in this order on a main surface of a substrate,

in which the thin film contains tin, tantalum, niobium, and oxygen, and

in which an oxygen deficiency rate of the thin film is 0.15 or more and 0.28 or less.

### (Configuration 2)

The reflective mask blank according to Configuration 1, in which a metal element having the largest content in the thin film is tin.

### (Configuration 3)

The reflective mask blank according to Configuration 1 or 2, in which an element having the largest content in the thin film is oxygen.

### (Configuration 4)

The reflective mask blank according to any of Configurations 1 to 3, in which the thin film contains tin, tantalum, niobium, and oxygen at a total content of 95 atom % or more.

### (Configuration 5)

The reflective mask blank according to any of Configurations 1 to 4, in which the thin film has a total oxygen content of 50 atom % or more.

### (Configuration 6)

The reflective mask blank according to any of Configurations 1 to 5, in which the thin film has an extinction coefficient k of 0.05 or more to light of 13.5 nm wavelength.

### (Configuration 7)

The reflective mask blank according to any of Configurations 1 to 6, in which the thin film has a thickness of 50 nm or less.

### (Configuration 8)

The reflective mask blank according to any of Configurations 1 to 7 including a protective film between the multilayer reflective film and the thin film.

### (Configuration 9)

A reflective mask including a multilayer reflective film and a thin film having a transfer pattern in this order on a main surface of a substrate,

in which the thin film contains tin, tantalum, niobium, and oxygen, and

in which an oxygen deficiency rate of the thin film is 0.15 or more and 0.28 or less.

### (Configuration 10)

The reflective mask according to Configuration 9, in which a metal element having the largest content in the thin film is tin.

### (Configuration 11)

The reflective mask according to Configuration 9 or 10, in which an element having the largest content in the thin film is oxygen.

### (Configuration 12)

The reflective mask according to any of Configurations 9 to 11, in which the thin film contains tin, tantalum, niobium, and oxygen at a total content of 95 atom % or more.

### (Configuration 13)

The reflective mask according to any of Configurations 9 to 12, in which the thin film has a total oxygen content of 50 atom % or more.

### (Configuration 14)

The reflective mask according to any of Configurations 9 to 13, in which the thin film has an extinction coefficient k of 0.05 or more to light of 13.5 nm wavelength.

### (Configuration 15)

The reflective mask according to any of Configurations 9 to 14, in which the thin film has a thickness of 50 nm or less.

### (Configuration 16)

The reflective mask according to any of Configurations 9 to 15 including a protective film between the multilayer reflective film and the thin film.

### (Configuration 17)

A method of manufacturing a semiconductor device including the step of transferring a transfer pattern to a resist film on a semiconductor substrate by exposure using the reflective mask according to any of Configurations 9 to 16.

### Effect of the Disclosure

The present disclosure can provide a reflective mask blank for manufacturing a reflective mask where shadowing effect is further reduced, which also includes an absorber film with enhanced chemical resistance. The present disclosure can provide a reflective mask where shadowing effect is further reduced, which also includes an absorber pattern with enhanced chemical resistance. The present disclosure can provide a method of manufacturing a semiconductor device having a fine and highly precise transfer pattern by using the reflective mask described above.

### BRIEF DESCRIPTION OF THE DRAWINGS

FIG. 1 is a cross-sectional schematic view showing a schematic configuration of a reflective mask blank according to the present disclosure.

FIGS. 2A-2D is a cross-sectional schematic view showing the steps of manufacturing a reflective mask from a reflective mask blank.

### EMBODIMENTS FOR CARRYING OUT THE DISCLOSURE

The embodiments of the present disclosure are explained below. First, the background of the present disclosure is explained. Regarding an absorber film (thin film for pattern formation) of a material containing tin (Sn) and oxygen (O), namely, an SnO-based material, the inventors intensively studied means for enhancing resistance (chemical resistance) to SPM cleaning, etc. while restraining reduction of an extinction coefficient k to EUV light. As a result, it was found that by forming the absorber film from a material including tantalum (Ta) and niobium (Nb) into SnO (i.e., a material containing tin, tantalum, niobium, and oxygen; hereinafter may be referred to as SnTaNbO-based material), chemical resistance was improved compared to an absorber film of an SnO-based material. At the same time, it was found that there were cases where chemical resistance was hardly improved depending on the composition of the SnTaNbO-based material used for an absorber film.

On the other hand, chlorine-based gas is often used as etching gas for dry etching in forming a pattern in an absorber film formed of an SnO-based material or an SnTaNbO-based material. However, it was found that an etching rate in dry etching using chlorine-based gas may significantly decrease depending on the configuration of an SnTaNbO-based material used for an absorber film.

Therefore, the inventors further studied to solve these problems. As a result, it was found that these problems occurred due to the difference in an oxygen deficiency rate of an SnTaNbO-based material forming an absorber film. An oxygen deficiency rate herein refers to a ratio obtained by dividing an actual oxygen content [atom %] of an SnTaNbO-based material by a theoretical oxygen content [atom %] assuming that the SnTaNbO-based material is in a stoichiometrically stable oxidation state (i.e., Sn, Nb, and Ta in the material are all present in SnO₂, Nb₂O₅, and Ta₂O₅; also referred to as complete oxidation state). The oxygen deficiency rate is calculated by [OI−OR]/OI, where OR is an oxygen content of an absorber film (thin film for pattern formation) of an SnTaNbO-based material, and OI is an ideal oxygen content where all Sn, Ta, and Nb are in a stoichiometrically stable oxide state.

An absorber film of an SnTaNbO-based material tends to have a slower etching rate of dry etching by chlorine-based gas than an absorber film of an SnO-based material. An absorber film of an SnTaNbO-based material tends to have less extinction coefficient k to EUV light than an absorber film of an SnO-based material. As an oxygen deficiency ratio of an absorber film of an SnTaNbO-based material becomes smaller, its etching rate approaches an etching rate of an absorber film of an SnO-based material. Further, as an oxygen deficiency ratio of an absorber film of an SnTaNbO-based material decreases, an extinction coefficient k to EUV light approaches the numerical value of an extinction coefficient k to EUV light of an SnO-based material. However, it was newly found that when an oxygen deficiency ratio of an absorber film of an SnTaNbO-based material is less than 0.15, chemical resistance greatly decreases and the significance of containing Ta and Nb is lost.

On the other hand, it was newly found that when an oxygen deficiency ratio of an absorber film of an SnTaNbO-based material is greater than 0.28, chemical resistance greatly decreases as well. It was also found that an etching rate of dry etching of an absorber film by chlorine-based gas is too slow, making it difficult to form a fine pattern in the absorber film. Furthermore, it was also found that an extinction coefficient k of an absorber film to EUV light becomes too small, causing excessively large film thickness for satisfying a predetermined reflectance. It is presumed that the above phenomenon occurs by the following mechanism. The study below is based on the presumption of the inventors as of the filing, which by no means limits the scope of the present disclosure.

A thin film for pattern formation such as an absorber film is generally formed through a sputtering method. Sn particles, Ta particles, and Nb particles floated out from a target are deposited onto a multilayer reflective film (or onto a protective film) on a substrate while incorporating oxygen in a film forming chamber on the way, respectively, to form a thin film. Ta and Nb particles tend to be oxidized more easily than Sn particles, and Ta and Nb particles are oxidized higher than and prior to Sn particles to form Ta₂O₅ particles and Nb₂O₅ particles. This means that the opportunity for Sn particles to oxidize is easily lost and difficult to form SnO₂ particles which are in a highly oxidized state. From these circumstances, it is considered that an SnTaNbO-based material forming an absorber film has a higher abundance ratio of Sn in a low oxidation state than an SnO-based material.

An SnO-based material tends to have a slower etching rate of dry etching by chlorine-based gas as an oxidation rate decreases (as an oxygen deficiency ratio increases). Further, a Ta0-based material and an Nb-based material tend to have a slower etching rate of dry etching by chlorine-based gas. On the other hand, an SnO-based material tends to have lower chemical resistance as a degree of oxidation decreases. Therefore, it is presumed that an absorber film of an SnTaNbO-based material having a high oxygen deficiency rate has a slow etching rate of dry etching by chlorine-based gas and a low chemical resistance.

As a result of the intensive study, in order to solve the above technical problem, the mask blank of the present disclosure is a reflective mask blank including a multilayer reflective film and a thin film for pattern formation in this order on a main surface of a substrate, featured in that the thin film contains tin, tantalum, niobium, and oxygen, and an oxygen deficiency rate of the thin film is 0.15 or more and 0.28 or less. Next, the embodiment of the present disclosure is described concretely below together with the drawings. Incidentally, the embodiment given below is one of the embodiments upon embodying the present disclosure and is not intended to limit the present disclosure within such a scope. Same reference numerals are applied to identical or corresponding portions in the drawings and descriptions therefor may be simplified or omitted.

### <Configuration of Reflective Mask Blank and Method of Manufacturing the Same>

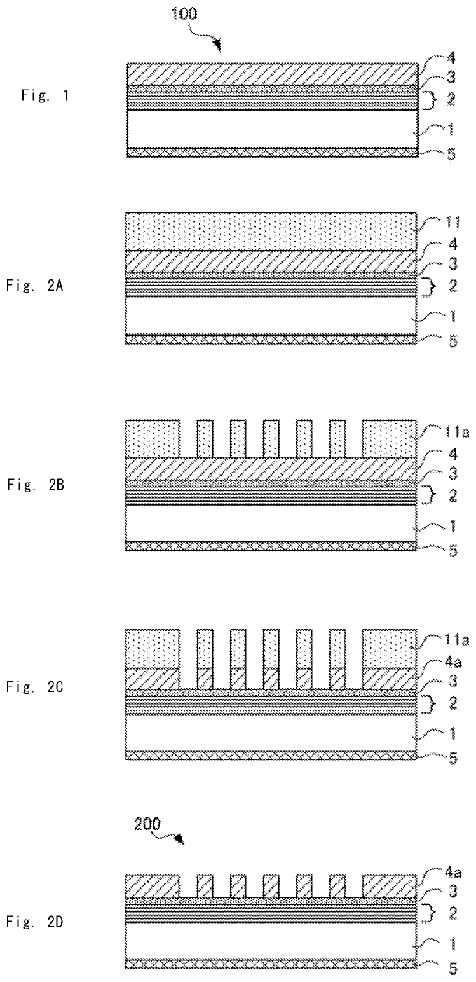

FIG. 1 is a cross-sectional schematic view of a principal portion for explaining the configuration of a reflective mask blank 100 according to an embodiment of the present disclosure. As shown in FIG. 1, the reflective mask blank 100 includes a substrate 1; a multilayer reflective film 2 formed on a first main surface (front surface) side and reflecting EUV light which is exposure light; a protective film 3 provided to protect the multilayer reflective film 2 and made of a material having resistance to cleaning liquid and an etchant used in patterning an absorber film 4 described below; and an absorber film 4 which absorbs EUV light, which are stacked in this order. A conductive film 5 for an electrostatic chuck is formed on a second main surface (back surface) side of the substrate 1.

In this specification, for example, the term “a multilayer reflective film 2 formed on the main surface of the substrate 1” means that the multilayer reflective film 2 is disposed in contact with the surface of the substrate 1, and also includes the case where another film is provided between the substrate 1 and the multilayer reflective film 2. The same applies to other films. Further in this specification, for example, “the film A is disposed on the film B in contact therewith” means that the film A and the film B are disposed in direct contact with each other without an interposing film between the film A and the film B.

Each configuration of the reflective mask blank 100 is concretely described below.

### «Substrate»

The substrate 1 preferably has a low thermal expansion coefficient of within the range of 0±5 ppb/° C. in order to prevent distortion of an absorber pattern due to heat during exposure by EUV light. As a material having a low thermal expansion coefficient in this range, for example, SiO₂—TiO₂ based glass, multicomponent glass ceramics, etc. can be used.

The first main surface of the substrate 1 on which a transfer pattern (configured from absorber pattern 4a described below) is formed is surface-processed to have a high flatness at least from the viewpoint of obtaining pattern transfer precision and position precision. In a region of 132 mm×132 mm or 142 mm×142 mm on the first main surface of the substrate 1 on the side where the transfer pattern is formed, the flatness is preferably 0.1 μm or less, more preferably 0.05 μm or less, and particularly preferably 0.03 μm or less. A second main surface on the side opposite to the side on which the absorber film 4 is formed is a surface to be electrostatically chucked when set in an exposure apparatus. In a region of 132 mm×132 mm or 142 mm×142 mm on the second main surface, the flatness is preferably 0.1 μm or less, more preferably 0.05 μm or less, and particularly preferably 0.03 μm or less.

A high surface smoothness of the substrate 1 is also a very important factor. A surface roughness of the first main surface of the substrate 1 in which an absorber pattern 4a is formed is preferably a root mean square roughness (RMS) of 0.1 nm or less. A surface smoothness can be measured by an atomic force microscope.

Further, the substrate 1 preferably has high rigidity in order to prevent deformation of a film to be formed thereon (such as the multilayer reflective film 2) due to film stress. In particular, the substrate 1 preferably has a high Young's modulus of 65 GPa or more.

### «Multilayer Reflective Film»

The multilayer reflective film 2 is to provide a function of reflecting EUV light in a reflective mask 200 shown in FIG. 2D, which is configured as a multilayer film in which each layer containing an element having different refractive index as a main component is stacked in cycles.

Generally, a multilayer film in which a thin film of a non-heavy element or a compound thereof of a high refractive index material (high refractive index layer) and a thin film of a heavy element or a compound thereof of a low refractive index material (low refractive index layer) are alternately stacked for about 40 to 60 cycles is used as the multilayer reflective film 2. The multilayer film may be formed by stacking a plurality of cycles, where one cycle consists of a stacked structure of high refractive index layer/low refractive index layer stacked in the order of the high refractive index layer and the low refractive index layer from the substrate 1 side; or may be formed by stacking a plurality of cycles, where one cycle consists of a stacked structure of low refractive index layer/high refractive index layer stacked in the order of the low refractive index layer and the high refractive index layer from the substrate 1 side. The uppermost layer of the multilayer reflective film 2, namely, the surface layer of the multilayer reflective film 2 on the side opposite to the substrate 1, is preferably the high refractive index layer. In the above-described multilayer film, in the case where the multilayer film is formed by stacking a plurality of cycles, where one cycle consists of a stacked structure of high refractive index layer/low refractive index layer stacked in the order of the high refractive index layer and the low refractive index layer from the substrate 1 side, the uppermost layer is the low refractive index layer. In this case, the low refractive index layer configuring the uppermost surface of the multilayer reflective film 2 easily promotes oxidation and causes reduction in reflectance of the reflective mask 200. Therefore, it is preferable to further form a high refractive index layer on the uppermost low refractive index layer to form the multilayer reflective film 2. On the other hand, in the above-described multilayer film, in the case of stacking a plurality of cycles, where one cycle consists of a stacked structure of low refractive index layer/high refractive index layer stacked in the order of the low refractive index layer and the high refractive index layer from the substrate 1 side, the high refractive index layer is disposed as the uppermost layer and therefore may be left unchanged.

In this embodiment, a layer containing silicon (Si) is employed as the high refractive index layer. The Si-containing material may be a simple Si, and also a Si compound containing Si and boron (B), carbon (C), nitrogen (N), and oxygen (O). By using a layer containing Si as the high refractive index layer, a reflective mask 200 having an excellent reflectance of EUV light can be obtained. In this embodiment, a glass substrate is preferably used as the substrate 1. Si is also excellent in adhesion with a glass substrate. As the low refractive index layer, a simple metal selected from molybdenum (Mo), ruthenium (Ru), rhodium (Rh), and platinum (Pt) or an alloy thereof is used. For example, as the multilayer reflective film 2 to EUV light having a wavelength of 13 nm to 14 nm, an Mo/Si cyclic stacked film in which Mo and Si films are alternately stacked for about 40 to 60 cycles is preferably used. A high refractive index layer, which is the uppermost layer of the multilayer reflective film 2, may be formed of silicon (Si), and a silicon oxide layer containing silicon and oxygen may be formed between the uppermost layer (Si) and an Ru-based protective film 3. This allows for enhancement in mask cleaning resistance.

A reflectance of the above-described multilayer reflective film 2 alone is usually 65% or more, and the upper limit is usually 73%. Thickness and cycle of each constituent layer of the multilayer reflective film 2 may be properly selected in accordance with the exposure wavelength, and selected to satisfy the Bragg's law of reflection. Although there are a plurality of high refractive index layers and a plurality of low refractive index layers in the multilayer reflective film 2, the thicknesses of the high refractive index layers with each other and the low refractive index layers with each other may not be the same. The film thickness of the Si layer at the uppermost surface of the multilayer reflective film 2 can be adjusted so as not to reduce reflectance. A film thickness of the uppermost Si (high refractive index layer) can be from 3 nm to 10 nm.

Although a method of forming the multilayer reflective film 2 is known in this technical field, the multilayer reflective film 2 can be formed by forming each layer thereof by, for example, an ion beam sputtering method. In the case of the Mo/Si cyclic multilayer film described above, for example, an Si film having a thickness of about 4 nm is first formed on the substrate 1 by ion beam sputtering using an Si target, and thereafter an Mo film having a thickness of about 3 nm is formed by using an Mo target, and with the above as one cycle, the cycles are stacked for 40 to 60 cycles to form the multilayer reflective film 2 (Si layer for uppermost layer). Upon formation of the multilayer reflective film 2, it is preferable that the multilayer reflective film 2 is formed by performing ion beam sputtering with krypton (Kr) ion particles supplied from an ion source.

### «Protective Film»

The reflective mask blank 100 of the embodiment of the present disclosure preferably has a protective film 3 between the multilayer reflective film 2 and the absorber film 4.

The protective film 3 is formed on the multilayer reflective film 2 to protect the multilayer reflective film 2 from dry etching and cleaning in the manufacturing process of the reflective mask 200, which will be described later. The protective film 3 also has a function of the protection of the multilayer reflective film 2 upon black defect repair of an absorber pattern 4a using an electron beam (EB). The protective film 3 can be formed of a material containing ruthenium as a main component. Namely, the material of the protective film 3 may be a simple Ru metal, or may be an Ru alloy containing Ru and at least one metal selected from titanium (Ti), niobium (Nb), molybdenum (Mo), zirconium (Zr), yttrium (Y), boron (B), lanthanum (La), cobalt (Co), rhenium (Re), etc., and may contain nitrogen. While FIG. 1 shows the case where the protective film 3 has one layer, a stacked structure of two or more layers can be employed. For example, in the case where the protective film 3 has a stacked structure of three layers, the lowermost layer and the uppermost layer of the protective film 3 may be a layer made of a substance containing Ru, and an intermediate layer containing metal other than Ru, or an alloy may be interposed between the lowermost layer and the uppermost layer. The protective film 3 as described above is effective in patterning the absorber film 4 by dry etching of chlorine-based gas. The protective film 3 is preferably formed of a material having an etching selectivity ratio of the absorber film 4 to the protective film 3 in dry etching using chlorine-based gas (etching rate of the absorber film 4/etching rate of the protective film 3) of 1.5 or more, preferably 3 or more.

An Ru content of the Ru alloy is 50 atom % or more and less than 100 atom %, preferably 80 atom % or more and less than 100 atom %, and more preferably 95 atom % or more and less than 100 atom %. In particular, when an Ru content of Ru alloy is 95 atom % or more and less than 100 atom %, it is possible to provide mask cleaning resistance, an etching stopper function when the absorber film 4 is etched, and a function as the protective film 3 for preventing the change of the multilayer reflective film 2 over time while restraining diffusion of constituent elements (silicon) of the multilayer reflective film 2 to the protective film 3 and also sufficiently ensuring a reflectance of EUV light.

In EUV lithography, since there are not many materials that are transparent to EUV light, an EUV pellicle for preventing foreign matter from adhering to a mask pattern surface is not technically easy. Therefore, a pellicle-less operation without using a pellicle is the mainstream. In EUV lithography, exposure contamination occurs such as deposition of a carbon film or growth of an oxide film on a mask by EUV light. Therefore, it is necessary to remove foreign substances and contamination on a mask by frequent cleaning at the stage of using the reflective mask 200 for manufacturing a semiconductor device. For this reason, the reflective mask 200 is required to have an extraordinary mask cleaning resistance than that of a transmissive mask for optical lithography. When an Ru-based protective film 3 containing Ti is used, a cleaning resistance is particularly high with respect to cleaning liquid such as sulfuric acid, sulfuric peroxide mixture (SPM), ammonia, ammonium hydrogen-peroxide mixture (APM), OH radical cleaning water, or ozone water having a concentration of l0ppm or less, and the demand for mask cleaning resistance can be satisfied.

A thickness of the protective film 3 made of Ru or its alloy or the like as mentioned above is not particularly limited as long as a function as the protective film 3 can be exhibited. From the viewpoint of a reflectance of EUV light, a thickness of the protective film 3 is preferably from 1.0 nm to 8.0 nm, more preferably from 1.5 nm to 6.0 nm.

As a method of forming the protective film 3, methods similar to known film forming methods can be employed without any particular limitation. Specific examples include DC sputtering, RF sputtering, and ion beam sputtering.

### «Absorber Film (Thin Film for Pattern Formation)»

The absorber film (thin film for pattern formation) 4 of this embodiment contains tin, tantalum, niobium, and oxygen, and is formed of a material having an oxygen deficiency rate of 0.15 or more and 0.28 or less. By forming the absorber film 4 in such a configuration, it is possible to restrain a decrease in an etching rate of dry etching of an absorber film of an SnO-based material by chlorine-based gas while improving chemical resistance to SPM cleaning in particular, as compared to an absorber film of an SnO-based material. Without tantalum and niobium contained in the absorber film 4, the chemical resistance to cleaning liquid is not improved even if the oxygen deficiency rate is set within the above range.

The absorber film 4 is required to have an oxygen deficiency rate of 0.15 or more, preferably 0.152 or more, and more preferably 0.154 or more. This is to increase an extinction coefficient k of the absorber film 4 while enhancing chemical resistance to cleaning liquid. On the other hand, the absorber film 4 is required to have an oxygen deficiency rate of 0.28 or less, preferably 0.25 or less, and more preferably 0.22 or less. This is to enhance chemical resistance to cleaning liquid while restraining a decrease in an etching rate of dry etching of the absorber film 4 by chlorine-based gas.

The metal element having the largest content in the absorber film 4 is preferably tin. By forming the absorber film 4 containing tin as the main metal element, an extinction coefficient k can be made larger than that of the absorber film 4 containing tantalum as the main metal element. A tin content of the absorber film 4 is preferably 30 atom % or more, more preferably 33 atom % or more, and even more preferably 35 atom % or less. This is to increase an extinction coefficient k of the absorber film 4. On the other hand, a tin content of the absorber film 4 is preferably 39 atom % or more, more preferably 38 atom % or more, and even more preferably 37 atom % or less. This is because the absorber film 4 needs to contain tantalum and tin, and further needs to contain a large amount of oxygen to restrain excessive oxygen deficiency rate.

In order to have each of the above effects, it is desirable that the absorber film 4 contains tin, tantalum, niobium, and oxygen as main constituent elements. A total content of tin, tantalum, niobium, and oxygen in the absorber film 4 is preferably 95 atom % or more, more preferably 97 atom % or more, and even more preferably 98 atom % or more. The absorber film 4 may contain elements other than tin, tantalum, niobium, and oxygen if a total content is within the range of less than 5 atom %.

A total content of tantalum and niobium in the absorber film 4 is preferably 3 atom % or more, more preferably 5 atom % or more, and even more preferably 6 atom % or more. This is to enhance chemical resistance of the absorber film 4 to cleaning liquid. On the other hand, a total content of tantalum and niobium in the absorber film 4 is preferably 20 atom % or less, more preferably 15 atom % or less, and even more preferably 12 atom % or less. This is to restrain a decrease in an etching rate of dry etching of the absorber film 4 by chlorine-based gas.

A tantalum content of the absorber film 4 is preferably 3 atom % or more, more preferably 4 atom % or more, and even more preferably 5 atom % or more. This is to enhance chemical resistance of the absorber film 4 to cleaning liquid. On the other hand, a total tantalum content of the absorber film 4 is preferably 14 atom % or less, more preferably 12 atom % or less, and even more preferably 10 atom % or less. This is to restrain a decrease in an etching rate of dry etching of the absorber film 4 by chlorine-based gas.

A niobium content of the absorber film 4 is preferably more than 0.1 atom %, and more preferably 0.2 atom % or more. This is to enhance chemical resistance of the absorber film 4 to cleaning liquid. On the other hand, a niobium content of the absorber film 4 is preferably 5 atom % or less, more preferably 4 atom % or less, and even more preferably 3 atom % or less. This is to restrain a decrease in the etching rate of dry etching of the absorber film 4 by chlorine-based gas.

An oxygen content of the absorber film 4 is preferably 50 atom % or more, more preferably 51 atom % or more, and even more preferably 52 atom % or more. This is to increase an extinction coefficient k of the absorber film 4 while enhancing chemical resistance to cleaning liquid. On the other hand, an oxygen content of the absorber film 4 is preferably less than 57.2 atom %, and more preferably 57.1 atom % or less. This is to enhance chemical resistance to cleaning liquid while restraining a decrease in an etching rate of dry etching of the absorber film 4 by chlorine-based gas.

An extinction coefficient k of the absorber film 4 to light of 13.5 nm wavelength is preferably 0.05 or more, and more preferably 0.051 or more. This makes it possible to reduce a reflectance to EUV light to a predetermined value or less while reducing the thickness of the absorber film 4. A refractive index n of the absorber film 4 to light of 13.5 nm wavelength is preferably 0.95 or less. Further, a refractive index n of the absorber film 4 to light of 13.5 nm wavelength is preferably 0.93 or more. A refractive index n and an extinction coefficient k herein are average values of the overall absorber film 4.

The thickness of the absorber film 4 is preferably 50 nm or less, more preferably 45 nm or less, and even more preferably 40 nm or less. This is to restrain the shadowing effect while keeping the reflectance of EUV light to the absorber film 4 at 1% or less.

The absorber film 4 may be a single-layer film or a multilayer film consisting of two or more layers. However, even in the case of the absorber film 4 of a multilayer film, it is necessary to satisfy the condition that all layers contain tin, tantalum, niobium, and oxygen, and have an oxygen deficiency rate of 0.15 or more and 0.28 or less. On the other hand, the absorber film 4 can have a structure with a composition gradient in the film thickness direction. In the case of the absorber film 4 having a composition gradient as well, it is necessary to satisfy the condition that all regions in the absorber film 4 contain tin, tantalum, niobium, and oxygen, and have an oxygen deficiency rate of 0.15 or more and 0.28 or less.

The absorber film 4 can be formed by a known method such as DC sputtering, RF sputtering, and ion beam sputtering. For example, the absorber film 4 may be formed by sputtering using a target containing a mixture of SnO₂, Ta₂O₅, and Nb₂O₅. Alternatively, the absorber film 4 may be formed by sputtering in which an SnO₂ target, a Ta₂O₅ target, and an Nb₂O₅ target are simultaneously discharged. Alternatively, the absorber film 4 may be formed by reactive sputtering using a target containing a mixture of Sn, Ta, and Nb in sputtering gas containing oxygen-containing gas. Alternatively, the absorber film 4 may be formed by simultaneously discharging a target containing a mixture of an Sn target, a Ta target, and an Nb target, and by reactive sputtering in sputtering gas containing oxygen-containing gas.

On the other hand, the reflective mask blank 100 of this embodiment can be configured to have an anti-reflective film on the absorber film 4. It is preferable that the anti-reflective film has a function to obtain a sufficient contrast between a reflectance of the anti-reflective film when DUV light (especially light of 193 nm wavelength) is irradiated and a reflectance of the multilayer reflective film 2 when the multilayer reflective film 2 is exposed (in the case where the protective film 3 is provided on the multilayer reflective film 2, reflectance of the protective film 3 with the protective film 3 exposed). The reflective mask 200 manufactured from the reflective mask blank 100 provided with such an anti-reflective film can detect defects with high precision when a mask defect inspection is performed using DUV light as inspection light.

Etching gas used for dry etching the absorber film 4 is preferably chlorine-based gas. The chlorine-based gas may be gas such as Cl₂, SiCl₄, CHCl₃, CCl₄, and BCl₃, or mixed gas containing two or more gas selected from these gas, mixed gas containing one or more of the above gas and He in a predetermined ratio, or mixed gas containing one or more of the above gas and Ar in a predetermined ratio.

On the other hand, the reflective mask blank 100 of this embodiment may be configured to have an etching mask film on the absorber film 4 (on the anti-reflective film, if provided). In this case, the etching mask film preferably consists of a material containing chromium (Cr) or a material containing silicon (Si).

Providing the etching mask film makes it possible to reduce a film thickness of a resist film 11 when forming an absorber pattern 4a, and to form a transfer pattern in the absorber film 4 with high precision. As a material of the etching mask film, a material having high etching selectivity ratio of the absorber film 4 to the etching mask film is used.

Examples of the material of the etching mask film having high etching selectivity ratio with respect to the absorber film 4 include chromium and chromium compounds. Examples of chromium compounds can include materials containing chromium (Cr) and one or more elements selected from nitrogen (N), oxygen (O), carbon (C), boron (B), and hydrogen (H). In order to increase the etching selectivity ratio with chlorine-based gas, it is preferable to form the etching mask film with a material that is substantially free of oxygen. A Cr content of the chromium compound of the etching mask film is preferably 50 atom % or more and less than 100 atom %, and more preferably 80 atom % or more and less than 100 atom %. The term “substantially free of oxygen” refers to a chromium compound having an oxygen content of 10 atom % or less, preferably 5 atom % or less. The material may contain metals other than chromium to the extent that the effect of the embodiment of the present disclosure can be obtained.

A material of silicon or silicon compounds can be used as the etching mask film. Examples of silicon compounds include materials containing silicon (Si) and at least one element selected from nitrogen (N), oxygen (O), carbon (C), and hydrogen (H), and materials such as metal silicon (metal silicide) and metal silicon compound (metal silicide compound) containing metal in silicon or silicon compounds.

The thickness of the etching mask film is preferably 2 nm or more from the viewpoint of obtaining a function as an etching mask for precisely forming a transfer pattern in the absorber film 4. The thickness of the etching mask film is preferably 15 nm or less, and more preferably 10 nm or less, from the viewpoint of reducing the thickness of the resist film 11.

### «Conductive Film»

A conductive film 5 for an electrostatic chuck is generally formed on a second main surface (back surface) side of the substrate 1 (opposite to the surface on which the multilayer reflective film 2 is formed). Electrical characteristic (sheet resistance) required for the conductive film 5 is usually 100 Ω/□ (Ω/Square) or less. The conductive film 5 can be formed by, for example, sputtering using a metal or alloy target of chromium, tantalum, etc.

The material containing chromium (Cr) of the conductive film 5 is preferably Cr compounds containing Cr and at least one element selected from boron, nitrogen, oxygen, and carbon. Examples of the Cr compounds include CrN, CrON, CrCN, CrCON, CrBN, CrBON, CrBCN, and CrBOCN.

As a material containing tantalum (Ta) of the conductive film 5, it is preferable to use Ta (tantalum), an alloy containing Ta, or Ta compounds containing at least one of boron, nitrogen, oxygen, and carbon in any of the above. Examples of Ta compounds include TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, and TaSiCON.

A material containing tantalum (Ta) or chromium (Cr) preferably has less amount of nitrogen (N) present on the surface layer. Specifically, a nitrogen content of the surface layer of the conductive film 5 of a material containing tantalum (Ta) or chromium (Cr) is preferably less than 5 atom %, and more preferably, substantially free of nitrogen in the surface layer. This is because the conductive film 5 of a material containing tantalum (Ta) or chromium (Cr) having less nitrogen content in the surface layer has higher wear resistance.

The conductive film 5 preferably consists of a material containing tantalum and boron. By the conductive film 5 consisting of a material containing tantalum and boron, the conductive film 23 having wear resistance and chemical resistance can be obtained. In the case where the conductive film 5 contains tantalum (Ta) and boron (B), a boron content is preferably 5 to 30 atom %. A ratio of Ta and B (Ta:B) in a sputtering target used for forming the conductive film 5 is preferably 95:5 to 70:30.

While a thickness of the conductive film 5 is not particularly limited as long as the function as an electrostatic chuck is satisfied, the thickness is generally between 10 nm and 200 nm. The conductive film 5 also adjusts the stress on the second main surface side of the mask blank 100. Therefore, the film thickness of the conductive film 5 is adjusted so as to obtain a flat reflective mask blank 100 in balance with stresses from various films formed on the first main surface side.

According to the reflective mask blank 100 (reflective mask 200 produced thereby) of this embodiment, a shadowing effect can be restrained by reducing a film thickness of the absorber film 4, and a fine and highly precise absorber pattern 4a can be formed with a stable cross-sectional shape having less sidewall roughness. The cleaning resistance of the absorber film 4 (absorber pattern 4a) can be improved. Therefore, in the reflective mask 200 manufactured by using the reflective mask blank 100 having this structure, the absorber pattern 4a itself formed on the mask can be formed finely and with high precision, and reduction in precision upon transfer due to shadowing can be prevented. Further, by performing EUV lithography using the reflective mask 200, it is possible to provide a method of manufacturing a fine and highly precise semiconductor device.

### <Reflective Mask and its Manufacturing Method>

The reflective mask 200 of this embodiment shown in FIG. 2D is featured in that a multilayer reflective film 2 and a thin film (absorber pattern) 4a having a transfer pattern formed therein are provided in this order on a main surface of a substrate 1, the thin film 4a contains tin, tantalum, niobium, and oxygen, and an oxygen deficiency rate of the thin film 4a is 0.15 or more and 0.28 or less. Each configuration of the reflective mask 200 is the same as that of the reflective mask blank 100. A method of manufacturing the reflective mask 200 using the reflective mask blank 100 shown in FIG. 1 is explained below together with FIGS. 2A-2D.

In the method of manufacturing the reflective mask 200 of this embodiment, the reflective mask blank 100 is prepared, and a resist film 11 is formed on an absorber film 4 of a first main surface thereof (FIG. 2A). This step is unnecessary in the case of including the resist film 11 as the reflective mask blank 100. A desired pattern is written (exposed) on the resist film 11, and further developed and rinsed to form a predetermined resist pattern 11a (FIG. 2B).

In the manufacturing method of this embodiment, the absorber film 4 is etched using the resist pattern 11a as a mask to form an absorber pattern 4a (FIG. 2C). The resist pattern 11a is removed by asking or wet process using hot sulfuric acid, etc. to form the absorber pattern 4a (FIG. 2D). Finally, wet cleaning using acidic or alkaline aqueous solution is performed.

The above-mentioned chlorine-based gas is used as the etching gas of the absorber film 4 in accordance with the material of the absorber film 4. In etching of the absorber film 4, etching gas is preferably substantially free of oxygen. This is because when etching gas is substantially free of oxygen, surface roughness does not occur in an Ru-based protective film 3. The gas substantially free of oxygen herein is gas with an oxygen content of 5 atom % or less.

Through the above-described process, the reflective mask 200 having less shadowing effect and high cleaning resistance to chemical solution (especially SPM cleaning) can be obtained.

### <Method of Manufacturing Semiconductor Device>

The method of manufacturing a semiconductor device according to the embodiment of the present disclosure includes the step of setting the aforementioned reflective mask 200 on an exposure apparatus using EUV light as an exposure light source, and transferring a transfer pattern onto a resist film formed on a substrate to be transferred.

By performing EUV exposure using the reflective mask 200 of this embodiment, a desired transfer pattern based on the absorber pattern 4a on the reflective mask 200 can be formed on the semiconductor substrate while restraining reduction in precision of transfer dimension due to a shadowing effect. Further, since the absorber pattern 4a is a fine and highly precise pattern with little sidewall roughness, a desired pattern can be formed on the semiconductor substrate with high dimensional precision. A semiconductor device having a desired electronic circuit formed thereon can be manufactured by performing various steps such as etching of a film or films to be processed, formation of an insulating film and a conductive film, introduction of a dopant, and annealing, in addition to the lithography step.

More specifically, an EUV exposure apparatus includes a laser plasma light source that generates EUV light, an illumination optical system, a mask stage system, a reduction projection optical system, a wafer stage system, vacuum equipment, etc. The light source is provided with a debris trap function, a cut filter for cutting light of a long wavelength other than exposure light, and equipment for vacuum differential evacuation, etc. The illumination optical system and the reduction projection optical system are composed of a reflective mirror. The reflective mask 200 is electrostatically adsorbed by a conductive film formed on a second main surface thereof and placed on a mask stage.

EUV light is irradiated on the reflective mask 200 via an illumination optical system at an angle inclined by 6° to 8° with respect to an orthogonal surface of the reflective mask 200. Reflected light from the reflective mask 200 relative to the incident light is reflected (specularly reflected) in the direction opposite to the incident light and at the same angle as the incident angle, and guided to the reflective projection optical system generally having a reduction ratio of 1/4, and exposed to a resist on a wafer (semiconductor substrate) placed on a wafer stage. During this stage, at least a location where EUV light passes is evacuated. The mainstream of this exposure is a scanning exposure, in which a mask stage and a wafer stage are scanned synchronously at a speed corresponding to a reduction ratio of a reduction projection optical system and the exposure is performed through a slit. By developing the exposed resist film, a resist pattern can be formed on the semiconductor substrate. In the embodiment of the present disclosure, a mask having a thin film having less shadowing effect and a highly precise absorber pattern 4a with less sidewall roughness is used. Therefore, a resist pattern formed on the semiconductor substrate results in a desired resist pattern having high dimensional precision. By using the resist pattern as a mask and performing etching, etc., for example, a predetermined wiring pattern can be formed on a semiconductor substrate. The semiconductor device is manufactured through the exposure step as mentioned above, and other necessary steps such as processing of a film or films to be processed, formation of an insulating film and a conductive film, introduction of a dopant, or annealing.

### EXAMPLES

The examples are described below together with the drawings. The embodiments are not limited to these examples. In each example, an identical reference numeral is applied to similar components and explanation thereof is omitted or simplified.

### Example 1

As Example 1, a reflective mask blank 100 having the structure shown in FIG. 1 was manufactured. The reflective mask blank 100 includes a conductive film 5, a substrate 1, a multilayer reflective film 2, a protective film 3, and an absorber film 4. A SiO₂-TiO₂-based low thermal expansion glass of 6025 size (about 152 mm×152 mm×6.35 mm) having both of a first main surface and a second main surface polished was prepared as the substrate 1. To obtain flat, smooth main surfaces, polishing steps including a rough polishing process, a precision polishing process, a local polishing process, and a touch polishing process were performed.

The conductive film 5 was formed with a thickness of 20 nm on the second main surface (back surface) of the SiO₂-TiO₂-based glass substrate 1. Concretely, the conductive film 5 was formed using a Cr target by DC magnetron sputtering (reactive sputtering) in mixed gas of Ar and N₂ (Ar:90%, N:10%).

Next, the multilayer reflective film 2 was formed on the main surface (first main face) on the substrate 1 that is opposite to the side on which the conductive film 5 was formed. The multilayer reflective film 2 formed on the substrate 1 was formed as a cyclic multilayer reflective film consisting of Mo and Si so that the multilayer reflective film 2 is suitable for EUV light of 13.5 nm wavelength. The multilayer reflective film 2 was formed by alternately stacking an Mo layer and an Si layer on the substrate 1 using an Mo target and an Si target and by ion beam sputtering in Ar gas atmosphere. First, an Si film was formed with a thickness of 4.2 nm and an Mo film with a thickness of 2.8 nm. With these films as one cycle, forty cycles were stacked similarly, and finally an Si film was formed with a thickness of 4.0 nm and the multilayer reflective film 2 was formed. While forty cycles were formed in this example, it is not limited thereto, and for example, sixty cycles can be formed. While the number of steps increase in sixty cycles compared to forty cycles, a reflectance to EUV light can be enhanced.

Next, the protective film 3 consisting of an Ru film was formed with a thickness of 2.5 nm in an Ar gas atmosphere using an Ru target by ion beam sputtering.

Next, the absorber film (SnTaNbO film) 4 consisting of tin, tantalum, niobium, and oxygen was formed with a thickness of 36.2 nm on the protective film 3. Concretely, the absorber film 4 was formed using a mixed target of SnO₂, Ta₂O₅, and Nb₂O₅, and by DC magnetron sputtering in xenon (Xe) gas.

Next, the SnTaNbO film of Example 1 was formed on another substrate through the same procedure. Measurements and calculations were conducted on the SnTaNbO film of Example 1. The results are given below.
(1) Refractive index n and extinction coefficient k at a wavelength of 13.5 nm
   refractive index n=0.9325, extinction coefficient k=0.0589
(2) Reflectance at a wavelength of 13.5 nm
   =1% or less
(3) Composition measured by X-ray photoelectron spectroscopy analysis (atom %)
   Sn:Ta:Nb:O=36.1:6.6:0.2:57.1
(4) Oxygen content OR measured by X-ray photoelectron spectroscopy analysis
   =57.1 [atom %]
(5) Oxygen content OI of an ideal state in a stoichiometrically stable oxide condition
   =67.5 [atom %]
(6) Oxygen deficiency rate [OI-OR]/OI
   =0.154
(7) Etching rate of dry etching when chlorine gas is used as etching gas
   =0.330 [nm/sec]
(8) Film reduction rate upon SPM cleaning
   =0.007 [nm/min]
Condition of SPM cleaning
   Mixing ratio of cleaning liquid:
      sulfuric acid:hydrogen peroxide solution=2:1 (volume ratio)
   Temperature: 80 to 100° C.
   Immersion time: 30 minutes

From the above results, it was found that the absorber film 4 of Example 1 has sufficiently fast etching rate to etching gas of chlorine-based gas and sufficiently high cleaning resistance to SPM cleaning.

Next, a reflective mask 200 of Example 1 was manufactured using the reflective mask blank 100 of Example 1.

As mentioned above, a resist film 11 was formed with a thickness of 100 nm on the absorber film 4 of the reflective mask blank 100 (FIG. 2A). A desired pattern was written (exposed) on the resist film 11, and further developed and rinsed to form a predetermined resist pattern 11a (FIG. 2B). Next, with the resist pattern 11a as a mask, dry etching of the absorber film 4 was conducted using Cl₂ gas to form an absorber pattern 4a (FIG. 2C). Thereafter, the resist pattern 11a was removed by asking or by resist peeling liquid. Finally, wet cleaning was conducted using pure water (DIW) and the reflective mask 200 was manufactured (FIG. 2D).

On the manufactured reflective mask 200, the shape of the pattern was observed using a length measurement SEM (CD-SEM: Critical Dimension Scanning Electron Microscope), confirming that the cross-sectional shape of the absorber pattern 4a was satisfactory. The reflective mask 200 of Example 1 was subjected to SPM cleaning, and film reduction of the absorber pattern 4a was slight, confirming sufficient cleaning resistance.

Next, the reflective mask 200 of Example 1 after SPM cleaning was set on an exposure apparatus using EUV light as exposure light, and a wafer having a film to be processed and a resist film formed on a semiconductor substrate was transferred by exposure. By developing the exposed resist film, a resist pattern was formed on the semiconductor substrate having formed thereon the film to be processed, and it was confirmed that a fine pattern was precisely transferred. The absorber pattern 4a of the reflective mask 200 of Example 1 had significantly less film thickness than a conventional absorber film 4 formed of a Ta-based material, and a shadowing effect was reduced.

A semiconductor device having desired characteristics was manufactured by transferring the resist pattern on the film or films to be processed by etching, and through various steps such as formation of an insulating film and a conductive film, introduction of a dopant, and annealing.

### Example 2

A mask blank 100 of Example 2 was manufactured by the same structure and method as Example 1 except for the change in the configuration of the absorber film 4.

An absorber film 4 (SnTaNbO film) of Example 2 was formed with a thickness of 43.3 nm on a protective film 3. The absorber film 4 was formed using a target with SnO₂, Ta₂O₅, and Nb₂O₅ in different mixing ratio than Example 1, and by DC magnetron sputtering in xenon (Xe) gas.

Next, the SnTaNbO film of Example 2 was formed on another substrate through the same procedure as Example 1. Measurements and calculations were conducted on the SnTaNbO film of Example 2. The results are given below.
(1) Refractive index n and extinction coefficient k at a wavelength of 13.5 nm
   refractive index n=0.9333, extinction coefficient k=0.0576
(2) Reflectance at a wavelength of 13.5 nm
   =1% or less
(3) Composition measured by X-ray photoelectron spectroscopy analysis (atom %)
   Sn:Ta:Nb:O=35.5:7.3:0.6:56.6
(4) Oxygen content OR measured by X-ray photoelectron spectroscopy analysis
   =56.6[atom %]
(5) Oxygen content OI of an ideal state in a stoichiometrically stable oxide condition
   =67.6[atom %]
(6) Oxygen deficiency rate [OI-OR]/OI
   =0.163
(7) Etching rate of dry etching when chlorine gas is used as etching gas
   =0.280[nm/sec]
(8) Film reduction rate upon SPM cleaning (same cleaning condition as Example 1)
   =0.008[nm/min]

From the above results, it was found that the absorber film 4 of Example 2 has a sufficiently fast etching rate to etching gas of chlorine-based gas and a sufficiently high cleaning resistance to SPM cleaning.

A reflective mask 200 of Example 2 was manufactured similarly as Example 1 and the shape of the pattern was observed by a length measurement SEM, confirming that the cross-sectional shape of the absorber pattern 4a was satisfactory. The reflective mask 200 of Example 2 was subjected to SPM cleaning, and film reduction of the absorber pattern 4a was slight, confirming sufficient cleaning resistance.

Similar to Example 1, the reflective mask 200 of Example 2 after SPM cleaning was set on an exposure apparatus using EUV light as exposure light, and a wafer having a film to be processed and a resist film formed on a semiconductor substrate was transferred by exposure. A resist pattern was formed and it was confirmed that a fine pattern was precisely transferred. The absorber pattern 4a of the reflective mask 200 of Example 2 had significantly less film thickness than a conventional absorber film 4 formed of Ta-based material, and the shadowing effect was reduced.

A semiconductor device having desired characteristics was manufactured by transferring the resist pattern on the film or films to be processed by etching, and through various steps such as formation of an insulating film and a conductive film, introduction of a dopant, and annealing.

### Example 3

A reflective mask blank 100 of Example 3 was manufactured by the same structure and method as Example 1 except for the change in the configuration of the absorber film 4.

An absorber film (SnTaNbO film) 4 of Example 3 was formed with a thickness of 44.3 nm on a protective film 3. The absorber film 4 was formed using a target with SnO₂, Ta₂O₅, and Nb₂O₅ in different mixing ratio than Example 1, and by DC magnetron sputtering in xenon (Xe) gas.

The SnTaNbO film of Example 3 was formed on another substrate through the same procedure as Example 1. Measurements and calculations were conducted on the SnTaNbO film of Example 3. The results are given below.
(1) Refractive index n and extinction coefficient k at a wavelength of 13.5 nm
   refractive index n=0.9454, extinction coefficient k=0.0515
(2) Reflectance at a wavelength of 13.5 nm
   =1% or less
(3) Composition measured by X-ray photoelectron spectroscopy analysis (atom %)
   Sn:Ta:Nb:O=35.2:8.6:2.5:53.7
(4) Oxygen content OR measured by X-ray photoelectron spectroscopy analysis
   =53.7 [atom %]
(5) Oxygen content OI of an ideal state in a stoichiometrically stable oxide condition
   67.9 [atom %]
(6) Oxygen deficiency rate [OI-OR]/OI
   =0.210
(7) Etching rate of dry etching when chlorine gas is used as etching gas
   =0.200 [nm/sec]
(8) Film reduction rate upon SPM cleaning (same cleaning condition as Example 1)
   =0.015 [nm/min]

From the above results, it was found that the absorber film 4 of Example 3 has a sufficiently fast etching rate to etching gas of chlorine-based gas and a sufficiently high cleaning resistance to SPM cleaning.

A reflective mask 200 of Example 3 was manufactured similarly as Example 1 and the shape of the pattern was observed by a length measurement SEM, confirming that the cross-sectional shape of the absorber pattern 4a was satisfactory. The reflective mask 200 of Example 3 was subjected to SPM cleaning, and film reduction of the absorber pattern 4a was slight, confirming sufficient cleaning resistance.

Similar to Example 1, the reflective mask 200 of Example 3 after SPM cleaning was set on an exposure apparatus using EUV light as exposure light, and a wafer having a film to be processed and a resist film formed on a semiconductor substrate was transferred by exposure. A resist pattern was formed and it was confirmed that a fine pattern was precisely transferred. The absorber pattern 4a of the reflective mask 200 of Example 3 had significantly less film thickness than a conventional absorber film 4 formed of a Ta-based material, and a shadowing effect was reduced.

A semiconductor device having desired characteristics was manufactured by transferring the resist pattern to the film or films to be processed by etching, and through various steps such as formation of an insulating film and a conductive film, introduction of a dopant, and annealing.

### Comparative Example 1

A reflective mask blank of Comparative Example 1 was manufactured by the same structure and method as Example 1 except for the change in the configuration of the absorber film.

An absorber film (SnTaNbO film) of Comparative Example 1 was formed with a thickness of 39.6 nm on a protective film. The absorber film was formed using a target with SnO₂, Ta₂O₅, and Nb₂O₅ in different mixing ratio than Example 1, and by DC magnetron sputtering in xenon (Xe) gas.

The SnTaNbO film of Comparative Example 1 was formed on another substrate through the same procedure as Example 1. Measurements and calculations were conducted on the SnTaNbO film of Comparative Example 1. The results are given below.
(1) Refractive index n and extinction coefficient k at a wavelength of 13.5 nm
   refractive index n=0.9394, extinction coefficient k=0.0606
(2) Reflectance at a wavelength of 13.5 nm
   =1% or less
(3) Composition measured by X-ray photoelectron spectroscopy analysis (atom %)
   Sn:Ta:Nb:O=39.9:2.8:0.1:57.2
(4) Oxygen content OR measured by X-ray photoelectron spectroscopy analysis
   =57.2 [atom %]
(5) Oxygen content OI of an ideal state in a stoichiometrically stable oxide condition
   =67.0 [atom %]
(6) Oxygen deficiency rate [OI-OR]/OI
   =0.146
(7) Etching rate of dry etching when chlorine gas is used as etching gas
   =0.360 [nm/sec]
(8) Film reduction rate upon SPM cleaning (same cleaning condition as Example 1)
=0.045 [nm/min]

From the above results, it was found that the absorber film 4 of Comparative Example 1 has a sufficiently fast etching rate to etching gas of chlorine-based gas, but low cleaning resistance to SPM cleaning.

A reflective mask of Comparative Example 1 was manufactured similarly as Example 1 and the shape of the pattern was observed by a length measurement SEM, confirming that the cross-sectional shape of the absorber pattern was satisfactory. However, after the reflective mask of Comparative Example 1 was subjected to SPM cleaning, thinning of the absorber pattern occurred due to insufficient cleaning resistance, and a part of the fine pattern was eliminated. With the reflective mask of Comparative Example 1, a precise transfer on a resist film on a semiconductor substrate cannot be made by an exposure transfer using an exposure apparatus with EUV light as exposure light.

### Comparative Example 2

A reflective mask blank of Comparative Example 2 was manufactured by the same structure and method as Example 1 except for the change in the configuration of the absorber film.

The absorber film (SnTaNbO film) of Comparative Example 2 was formed with a thickness of 44.4 nm on a protective film. The absorber film was formed using a target with SnO₂, Ta₂O₅, and Nb₂O₅ in different mixing ratio than Example 1, and by DC magnetron sputtering in xenon (Xe) gas.

The SnTaNbO film of Comparative Example 2 was formed on another substrate through the same procedure as Example 1. Measurements and calculations were conducted on the SnTaNbO film of Comparative Example 2. The results are given below.
(1) Refractive index n and extinction coefficient k at a wavelength of 13.5 nm
   refractive index n=0.9402, extinction coefficient k=0.0500
(2) Reflectance at a wavelength of 13.5 nm
   =1% or less
(3) Composition measured by X-ray photoelectron spectroscopy analysis (atom %)
   Sn:Ta:Nb:O=29.9:14.9:5.9:49.3
(4) Oxygen content OR measured by X-ray photoelectron spectroscopy analysis
   =49.3 [atom %]
(5) Oxygen content OI of an ideal state in a stoichiometrically stable oxide condition
   =68.8 [atom %]
(6) Oxygen deficiency rate [OI-OR]/OI
   =0.283
(7) Etching rate of dry etching when chlorine gas is used as etching gas
   =0.120 [nm/sec]
(8) Film reduction rate upon SPM cleaning (same cleaning condition as Example 1)
   =0.038 [nm/min]

From the above results, it was found that the absorber film of Comparative Example 2 has a slow etching rate to etching gas of chlorine-based gas, and relatively low cleaning resistance to SPM cleaning.

A reflective mask 200 of Comparative Example 2 was manufactured similarly as Example 1 and the shape of the pattern was observed by a length measurement SEM, confirming that there are portions where the absorber pattern was not formed (absorber film that should be removed by etching was not completely removed). However, after the reflective mask of Comparative Example 2 was subjected to SPM cleaning, thinning of the absorber pattern occurred due to insufficient cleaning resistance, and a part of the fine pattern was eliminated. With the reflective mask 200 of Comparative Example 2, a precise transfer on a resist film on a semiconductor substrate cannot be made by an exposure transfer using an exposure apparatus with EUV light as exposure light.

### Comparative Example 3

A reflective mask blank of Comparative Example 3 was manufactured by the same structure and method as Example 1 except for the change in the configuration of the absorber film.

An absorber film of Comparative Example 3 is formed of a material consisting of tin and oxygen, and free of tantalum and niobium. Namely, the absorber film (SnO film) consisting of tin and oxygen was formed with a thickness of 36.4 nm on a protective film. Concretely, the absorber film was formed using an Sn target, and by DC magnetron sputtering in mixed gas of xenon (Xe) and oxygen (O₂).

The SnO film of Comparative Example 3 was formed on another substrate through the same procedure as Example 1. Measurements and calculations were conducted on the SnO film of Comparative Example 3. The results are given below.
(1) Refractive index n and extinction coefficient k at a wavelength of 13.5 nm
   refractive index n=0.9263, extinction coefficient k=0.0689
(2) Reflectance at a wavelength of 13.5 nm
   =1% or less
(3) Composition measured by X-ray photoelectron spectroscopy analysis (atom %)
   Sn:O=42.7:57.3
(4) Oxygen content OR measured by X-ray photoelectron spectroscopy analysis
   =57.3 [atom %]
(5) Oxygen content OI of an ideal state in a stoichiometrically stable oxide condition
   =66.7 [atom %]
(6) Oxygen deficiency rate [OI-OR]/OI
   =0.141
(7) Etching rate of dry etching when chlorine gas is used as etching gas
   =0.410 [nm/sec]
(8) Film reduction rate upon SPM cleaning (same cleaning condition as Example 1)
   =0.052 [nm/min]

From the above results, it was found that the absorber film 4 of Comparative Example 3 has a sufficiently fast etching rate to etching gas of chlorine-based gas, but low cleaning resistance to SPM cleaning.

A reflective mask of Comparative Example 3 was manufactured similarly as Example 1 and the shape of the pattern was observed by a length measurement SEM, confirming that the cross-sectional shape of the absorber pattern was satisfactory. However, after the reflective mask of Comparative Example 3 was subjected to SPM cleaning, thinning of the absorber pattern occurred due to insufficient cleaning resistance, and a part of the fine pattern was eliminated. With the reflective mask of Comparative Example 3, precise transfer on a resist film on a semiconductor substrate cannot be made by an exposure transfer using an exposure apparatus with EUV light as exposure light.

### Comparative Example 4

A reflective mask blank of Comparative Example 4 was manufactured by the same structure and method as Example 1 except for the change in the configuration of the absorber film.

An absorber film of Comparative Example 4 is formed of a material consisting of tin and oxygen, and free of tantalum and niobium. Namely, an absorber film (SnO film) consisting of tin and oxygen was formed with a thickness of 36.0 nm on a protective film. Concretely, the absorber film was formed using an Sn target, and by DC magnetron sputtering in mixed gas of xenon (Xe) and oxygen (O₂).

The SnO film of Comparative Example 4 was formed on another substrate through the same procedure as Example 1. Measurements and calculations were conducted on the SnO film of Comparative Example 4. The results are given below.
(1) Refractive index n and extinction coefficient k at a wavelength of 13.5 nm
   refractive index n=0.9268, extinction coefficient k=0.0690
(2) Reflectance at a wavelength of 13.5 nm
   =1% or less
(3) Composition measured by X-ray photoelectron spectroscopy analysis (atom %)
   Sn:O=44.1:55.9
(4) Oxygen content OR measured by X-ray photoelectron spectroscopy analysis
   55.9 [atom %]
(5) Oxygen content OI of an ideal state in a stoichiometrically stable oxide condition
   66.7 [atom %]
(6) Oxygen deficiency rate [OI-OR]/OI
   =0.162
(7) Etching rate of dry etching when chlorine gas is used as etching gas
   =0.240 [nm/sec]
(8) Film reduction rate upon SPM cleaning (same cleaning condition as Example 1)
   =0.055 [nm/min]

From the above results, it was found that the absorber film 4 of Comparative Example 4 has a sufficiently fast etching rate to etching gas of chlorine-based gas, but low cleaning resistance to SPM cleaning.

A reflective mask of Comparative Example 4 was manufactured similarly as Example 1 and the shape of the pattern was observed by a length measurement SEM, confirming that the cross-sectional shape of the absorber pattern was satisfactory. However, after the reflective mask of Comparative Example 4 was subjected to SPM cleaning, thinning of the absorber pattern occurred due to insufficient cleaning resistance, and a part of the fine pattern was eliminated. With the reflective mask of Comparative Example 4, a precise transfer on a resist film on a semiconductor substrate cannot be made by an exposure transfer using an exposure apparatus with EUV light as exposure light.

### DESCRIPTION OF REFERENCE NUMERALS

1. substrate
2. multilayer reflective film
3. protective film
4. absorber film (thin film)
4a absorber pattern (transfer pattern)
5. conductive film
11. resist film
11a. resist pattern
100. reflective mask blank
200. reflective mask

1. A reflective mask blank comprising a multilayer reflective film and a thin film for pattern formation in this order on a main surface of a substrate,
wherein the thin film contains tin, tantalum, niobium, and oxygen, and
wherein an oxygen deficiency rate of the thin film is 0.15 or more and 0.28 or less.

2. The reflective mask blank according to claim 1, wherein a metal element having the largest content in the thin film is tin.

3. The reflective mask blank according to claim 1, wherein an element having the largest content in the thin film is oxygen.

4. The reflective mask blank according to claim 1, wherein the thin film contains tin, tantalum, niobium, and oxygen at a total content of 95 atom % or more.

5. The reflective mask blank according to claim 1, wherein the thin film has a total oxygen content of 50 atom % or more.

6. The reflective mask blank according to claim 1, wherein the thin film has an extinction coefficient k of 0.05 or more to light of 13.5 nm wavelength.

7. The reflective mask blank according to claim 1, wherein the thin film has a thickness of 50 nm or less.

8. The reflective mask blank according to claim 1 comprising a protective film between the multilayer reflective film and the thin film.

9. A reflective mask comprising a multilayer reflective film and a thin film having a transfer pattern in this order on a main surface of a substrate,
wherein the thin film contains tin, tantalum, niobium, and oxygen, and
wherein an oxygen deficiency rate of the thin film is 0.15 or more and 0.28 or less.

10. The reflective mask according to claim 9, wherein a metal element having the largest content in the thin film is tin.

11. The reflective mask according to claim 9, wherein an element having the largest content in the thin film is oxygen.

12. The reflective mask according to claim 9, wherein the thin film contains tin, tantalum, niobium, and oxygen at a total content of 95 atom % or more.

13. The reflective mask according to claim 9, wherein the thin film has a total oxygen content of 50 atom % or more.

14. The reflective mask according to claim 9, wherein the thin film has an extinction coefficient k of 0.05 or more to light of 13.5 nm wavelength.

15. The reflective mask according to claim 9, wherein the thin film has a thickness of 50 nm or less.

16. The reflective mask according to claim 9 comprising a protective film between the multilayer reflective film and the thin film.

17. A method of manufacturing a semiconductor device comprising the step of transferring a transfer pattern to a resist film on a semiconductor substrate by exposure using the reflective mask according to claim 9.

18. The reflective mask according to claim 11, wherein the thin film contains tin, tantalum, niobium, and oxygen at a total content of 95 atom % or more.

19. The reflective mask according to claim 18, wherein the thin film has a total oxygen content of 50 atom % or more.

20. The reflective mask according to claim 19, wherein the thin film has an extinction coefficient k of 0.05 or more to light of 13.5 nm wavelength.
